(19) United States
(12) Patent Application Publication
(10) Pub. No.: US 2026/0234066 A1
(43) Pub. Date: Aug. 13, 2026

(54) BONDED BODY

(71) Applicant: NGK Corporation, Nagoya-shi (JP)

(72) Inventors: Masato MISAKI, Higashiura-cho (JP); Koichi YOSHINO, Nagoya-shi (JP); Akiyoshi HATTORI, Nagoya-shi (JP); Kazuhiro NOBORI, Handa-shi (JP)

(73) Assignee: NGK Corporation, Nagoya-shi (JP)

(21) Appl. No.: 19/649,409

(22) Filed: Apr. 16, 2026

Related U.S. Application Data
(63) Continuation of application No. PCT/JP2024/041015, filed on Nov. 19, 2024.

(30) Foreign Application Priority Data
Nov. 20, 2023 (WO) PCT/JP2023/041672

(51) Int. Cl. C04B 37/02; H01J 37/32; H10P 72/72

(52) U.S. Cl. CPC C04B 37/026; H01J 37/32467; H01J 37/32568; H01J 37/32724; C04B 2237/121; C04B 2237/343; C04B 2237/366; C04B 2237/68; H01J 2237/002; H01J 2237/2007; H10P 72/722

(57) ABSTRACT

Provided is a bonded body including a ceramic plate; a metal matrix composite (MMC) plate facing one side of the ceramic plate and made of an MMC comprising (i) Si, C, and Ti, or (ii) Al, Si, and C; and a bonding layer interposed between the ceramic plate and the MMC plate and bonding the ceramic plate and the MMC plate to each other, wherein the bonding layer comprises Al as a main component. The MMC plate includes an Al-rich layer in which Al is distributed at a higher concentration than in other regions of the MMC plate over a predetermined depth D_{Al} from a bonding interface between the bonding layer and the MMC plate, and the depth D_{Al} of the Al-rich layer is 40 μm or more.

### CROSS-REFERENCE TO RELATED APPLICATIONS

This application is a continuation application of PCT/JP2024/041015 filed Nov. 19, 2024, which claims priority to International Application No. PCT/JP2023/041672 filed Nov. 20, 2023, the entire contents all of which are incorporated herein by reference.

### BACKGROUND OF THE INVENTION

### 1. Field of the Invention

The present disclosure relates to a bonded body.

### 2. Description of the Related Art

Circuit formation in production of semiconductor devices is generally carried out by plasma etching. Plasma etching is carried out by introducing an inert gas into a vacuum chamber in a plasma etching system and converting it into plasma. A plasma etching system has an electrostatic chuck assembly provided therein that functions as a susceptor for mounting a wafer to be etched. A typical electrostatic chuck assembly includes an electrode embedded-ceramic plate functioning as an electrostatic chuck and a cooling plate supporting the bottom surface of the electrode embedded-ceramic plate. The wafer is electrostatically adsorbed to the ceramic plate with a built-in electrode to thereby be fixed on the electrostatic chuck assembly, and in that state, the wafer is plasma-etched. On the other hand, the cooling plate is provided on the bottom surface of the ceramic plate having a built-in electrode, and is thus configured to conduct away heat generated in the wafer by plasma etching. The electrode embedded-ceramic plate generally has a structure including: a ceramic base material made of aluminum oxide or aluminum nitride, which is excellent in heat resistance and corrosion resistance; and an inner electrode embedded therein, such as an electrostatic chuck (ESC) electrode, an RF electrode and a heater electrode.

Patent Literature 1 (JP2009-141204A) discloses a supporter for a substrate, as an example of an electrostatic chuck assembly, the supporter including a first ceramic sintered body as a first base material and a second ceramic sintered body as a second base material, wherein the first base material and the second base material are bonded to each other via a bonding metal film containing Al. In this literature, it is disclosed that the first base material and the second base material with the bonding metal film containing Al interposed therebetween are subjected to thermal compression bonding at a pressure of 4 to 20 MPa while the metal is being heated, so that the first base material and the second base material are bonded to each other via the bonding film. It is purported that the Al-containing metal is desirably an Al alloy containing Ma in a range from 0.5 to 5% by weight.

Recently, metal matrix composites (MMC) have attracted attention. The metal matrix composites are materials obtained by combining a metal matrix made of a metal such as Al or metallic Si with a reinforcing ceramic material such as SiC or TiC, and it is known that the metal matrix composites have advantages including light weight, high rigidity, high thermal conductivity, and small thermal expansion. Methods for bonding a metal matrix composite (MMC) and a ceramic material have been proposed, and in Patent Literature 2 (JP4373538B) discloses a bonded body including an MMC containing an aluminum alloy as a matrix and a ceramic material, wherein the MMC and the ceramic material is bonded to each other via a wax material made of an Al alloy containing Mg.

### CITATION LIST

### Patent Literature

Patent Literature 1: JP2009-141204A
Patent Literature 2: JP4373538B
Patent Literature 3: JP2006-196864A

### SUMMARY OF THE INVENTION

It is desirable to use an MMC plate as a cooling plate of an electrostatic chuck assembly, in light of advantages including high thermal conductivity and small thermal expansion. Thus, there is a need for improvement in bond strength between an MMC plate and a ceramic plate of a bonded body.

The inventors have found that a bonded body including a ceramic plate and an MMC plate and having a high bond strength can be provided by interposing a predetermined bonding layer between the MMC plate and the ceramic plate and allowing the MMC plate to have an Al-rich layer over a predetermined depth (thickness) from the bonding interface between the bonding layer and the MMC plate.

Thus, an object of the present invention is to provide a bonded body including a ceramic plate and an MMC plate and having a high bond strength.

The present disclosure provides the following aspects.

### [Aspect 1]

A bonded body comprising:
a ceramic plate;
a metal matrix composite (MMC) plate facing one side of the ceramic plate and made of an MMC comprising (i) Si, C, and Ti, or (ii) Al, Si, and C; and
a bonding layer interposed between the ceramic plate and the MMC plate and bonding the ceramic plate and the MMC plate to each other, wherein the bonding layer comprises Al as a main component,
wherein the MMC plate includes an Al-rich layer in which Al is distributed at a higher concentration than in other regions of the MMC plate over a predetermined depth D_{Al} from a bonding interface between the bonding layer and the MMC plate, and the depth D_{Al} of the Al-rich layer is 40 μm or more.

### [Aspect 2]

The bonded body according to aspect 1, wherein the metal matrix composite (MMC) comprises Si, C, and Ti, and further comprises Al, or Al and N.

### [Aspect 3]

The bonded body according to aspect 1 or 2, wherein the metal matrix composite (MMC) comprises Al, Si, and C.

### [Aspect 4]

The bonded body according to any one of aspects 1 to 3, wherein the bonding layer further comprises Si as a subcomponent.

### [Aspect 5]

The bonded body according to any one of aspects 1 to 4, wherein the bonding layer further comprises Mg as a subcomponent.

### [Aspect 6]

The bonded body according to aspect 5, wherein the MMC plate includes a Mg-diffused layer in which Mg derived from the bonding layer is diffused over a predetermined depth D_{Mg} from a bonding interface between the bonding layer and the MMC plate.

### [Aspect 7]

The bonded body according to aspect 6, wherein the depth D_{Al} of the Al-rich layer is greater than the depth D_{Mg} of the Mg-diffused layer to satisfy D_{Al}>D_{Mg}.

### [Aspect 8]

The bonded body according to any one of aspects 1 to 7, wherein the ceramic plate comprises aluminum oxide and/or aluminum nitride, and comprises an embedded inner electrode.

### [Aspect 9]

The bonded body according to any one of aspects 1 to 8, wherein the bonding of the ceramic plate, the bonding layer, and the MMC plate is thermal compression bonding.

### [Aspect 10]

The bonded body according to any one of aspects 1 to 10, wherein a surface of the MMC plate, on the bonding interface side, has an arithmetic mean roughness Ra of 0.01 to 1.0 μm.

### [Aspect 11]

The bonded body according to any one of aspects 1 to 7, having a bond strength of 200 MPa or more in four point bending test.

### BRIEF DESCRIPTION OF THE DRAWINGS

FIG. 1 is a schematic cross section illustrate an example of the bonded body according to the present invention.

FIG. 2 is a schematic cross section illustrate another example of the bonded body according to the present invention.

FIG. 3A shows an SEM image (Compo image) of a cross section including a ceramic plate 12, a bonding interface 20, and a bonding layer 16 of the bonded body according to Example 7, and the Si, C, and Ti mapping images of the area corresponding thereto.

FIG. 3B shows an SEM image (Compo image) of a cross section including a ceramic plate 12, a bonding interface 20, and a bonding layer 16 of the bonded body according to Example 7, and the O, Mg, and Al mapping images of the area corresponding thereto.

FIG. 4A shows an SEM image (Compo image) of a cross section including a bonding layer 16, a bonding interface 22, and an MMC plate 14 of the bonded body according to Example 7, and the Si, C, and Ti mapping images of the area corresponding thereto.

FIG. 4B shows an SEM image (Compo image) of a cross section including a bonding layer 16, a bonding interface 22, and an MMC plate 14 of the bonded body according to Example 7, and the O, Mg, and Al mapping images of the area corresponding thereto.

FIG. 5A shows another version of the SEM image (Compo image) of the cross section including a bonding layer 16, a bonding interface 22, and an MMC plate 14 of the bonded body according to Example 7, and the Si, C, and Ti mapping images of the area corresponding thereto, the elemental mapping images being versions on a reduced concentration scale.

FIG. 5B shows another version of the SEM image (Compo image) of the cross section including a bonding layer 16, a bonding interface 22, and an MMC plate 14 of the bonded body according to Example 7, and the O, Mg, and Al mapping images of the area corresponding thereto, the elemental mapping images being versions on a reduced concentration scale.

### DETAILED DESCRIPTION OF THE INVENTION

### Bonded Body

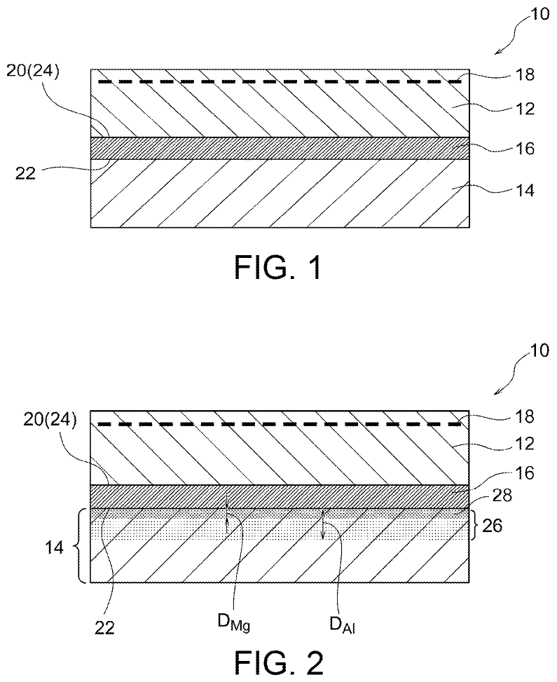

FIG. 1 shows an example of the bonded body according to the present invention. A bonded body 10 shown in FIG. 1 includes a ceramic plate 12, an MMC plate 14, and a bonding layer 16. Preferably, the ceramic plate 12 includes aluminum oxide and/or aluminum nitride and includes an embedded inner electrode 18. The MMC plate 14 is a plate made of a metal matrix composite (MMC) and is provided such that it faces one side of the ceramic plate 12. The metal matrix composite (MMC) contains (i) Si, C, and Ti, or (ii) Al, Si, and C. The bonding layer 16 is a layer bonding the ceramic plate 12 and the MMC plate 14 to each other and is interposed between the ceramic plate 12 and the MMC plate 14. The bonding layer 16 includes Al as a main component. As specifically illustrated in FIG. 2, the MMC plate 14 has an Al-rich layer 26 in which Al is distributed at a higher concentration than in other regions of the MMC plate 14 over a predetermined depth D_{Al} from the bonding interface 22 between the bonding layer 16 and the MMC plate 14. The depth D_{Al} of the Al-rich layer 26 is 40 μm or more. Thus, the bonded body 10 including the ceramic plate 12 and the MMC plate 14 and having a high bond strength can be provided by interposing a predetermined bonding layer 16 between the MMC plate 14 and the ceramic plate 12 and allowing the MMC plate 14 to include an Al-rich layer 26 over a predetermined depth (thickness) from the bonding interface 22 between the bonding layer 16 and the MMC plate 14. In other words, a higher bond strength between the MMC plate 14 and the ceramic plate 12 can be achieved by not only employing the predetermined bonding layer 16 but also providing the Al-rich layer 26.

The ceramic plate 12 is a plate-shaped member including a ceramic sintered body, and may have the same configuration as that of a ceramic plate employed for a known ceramic susceptor (e.g., an electrostatic chuck assembly or a ceramic heater). Typically, an inner electrode 18 is embedded in the ceramic plate 12. The ceramic sintered body serving as the main body (i.e., the ceramic base material) of the ceramic plate 12, excluding the inner electrode 18, preferably includes aluminum oxide and/or aluminum nitride, in terms of, for example, the excellent thermal conductivity, the high electrical insulation property, and the thermal expansion characteristic similar to that of silicon. In addition to the aluminum oxide and/or aluminum nitride, the ceramic sintered body included in the ceramic plate 12 may include an additive such as MgO. In this case, the content of the aluminum oxide and/or aluminum nitride in the ceramic sintered body included in the ceramic plate 12 is typically 50 to 100 mass %, and the remainder may include the additive such as MgO. The thickness of the ceramic plate 12 may be a thickness of a general ceramic plate and is not particularly limited. The thickness is typically 2 to 10 mm, and may be more typically 2 to 5 mm.

Examples of the inner electrode 18 embedded in the ceramic plate 12 include an ESC electrode, a heater electrode, and an RF electrode. Two types of inner electrodes 18 may be provided in the ceramic plate 12. The ESC electrode is the abbreviation of an electrostatic chuck (ESC) electrode and also referred to as an electrostatic electrode. The ESC electrode is preferably a circular thin-layer electrode having a slightly smaller diameter than that of the ceramic plate 12, and may be, for example, a mesh electrode in a sheet form obtained by weaving a thin metal wire into a net. The ESC electrode may be used as a plasma electrode. Specifically, a high-frequency wave can be applied to the ESC electrode to thereby use the ESC electrode as a plasma electrode, so that film formation can be carried out by the plasma CVD process. When a voltage is applied to the ESC electrode by an external power supply, the ESC electrode chucks a wafer mounted on the surface of the ceramic plate 12 by the Johnson-Rahbek effect. The heater electrode is not particularly limited, and may be, for example, a conductive coil that is wired throughout the whole area of the ceramic plate 12 in a unicursal manner. When a power is supplied to the heater electrode by a heater power supply, the heater electrode generates heat to heat a wafer mounted on the surface of the ceramic plate 12. The heater electrode is not limited to the coil, and may be ribbon (long and narrow, thin plate) or mesh. The heater electrode having the shape of ribbon may be formed by a printing method.

The MMC plate 14 is made of a metal matrix composite (MMC). The MMC is not particularly limited, and may be a known material obtained by combining a metal matrix with a reinforcing ceramic material. Examples of the metal matrix include aluminum and metallic silicon. Examples of the reinforcing ceramic material include SiC and TiC. In a preferred aspect of the present invention, the MMC may contain Si, C, and Ti. Examples of the MMC containing Si, C, and Ti include a composite material that contains 37 to 60 mass % of silicon carbide and also contains titanium silicon carbide and titanium carbide in respective amounts smaller than the content (mass %) of the silicon carbide. Other examples of the MMC containing Si, C, and Ti include a composite material that contains 42 to 65% by mass of titanium silicide (TiSi₂) and also contains SiC, titanium silicon carbide, and titanium carbide in the respective amounts smaller than the content of titanium silicide (TiSi₂). The MMC containing Si, C, and Ti may additionally contain Al, or Al and N. That is, the MMC containing Si, C, and Ti may additionally contain Al, and Al may be contained in a form accompanied by N, such as AlN. The Al additionally contained advantageously brings about an increased bond strength. Examples of the MMC containing Si, C, Ti, Al, and N include a composite material that contains 42 to 60% by mass titanium silicide and also contains SiC, titanium silicon carbide, titanium carbide, alumina, and aluminum nitride in the respective amounts smaller than the content (% by mass) of titanium silicide. In another preferred aspect of the present invention, the MMC contains Al, Si, and C. Examples of the MMC containing Al, Si, and C include a composite material that contains 60 to 80% by volume of SiC and also contains aluminum in an amount smaller than the SiC content (% by volume). The thickness of the MMC plate 14 is not particularly limited, and typically 5 to 35 mm.

The surface of the MMC plate 14, on the bonding interface 22 side, preferably has an arithmetic mean roughness Ra of 0.01 to 1.0 μm, and more preferably 0.05 to 0.70 μm. An arithmetic mean roughness Ra within the above range can more effectively enhance the bond strength. It is considered that the reason for this is that not too high an Ra enhances the adhesion of the MMC plate 14 to the bonding layer 16, and additionally that not too low an Ra brings about the anchor effect due to the surface roughness or unevenness of the MMC plate 14.

The bonding layer 16 is a metal layer containing Al as a main component. The bonding layer 16 preferably further contains Si and/or Mg as a subcomponent, and more preferably further contains Si, or Si and/or Mg as a subcomponent. Here, the “main component” means a component that accounts for 80% by weight or more of the bonding layer 16. The “subcomponent” is a component the content of which is smaller than that of the main component (but excluding inevitable impurities). Accordingly, the bonding material forming the bonding layer 16 is preferably an Al alloy containing Si without Mg, or an Al alloy containing Si and Mg. The Si content of the Al alloy is preferably 5 to 15% by weight. In a case where Mg is contained, the Mg content of the aluminum alloy is preferably 0.1 to 5.0% by weight. In other words, the bonding layer 16 is preferably made of an Al alloy containing 5 to 15% by weight of Si and 0.5 to 5.0% by weight of Mg and containing Al and inevitable impurities as the remainder. In a case where Mg is not contained, the bonding layer 16 is preferably made of an Al alloy containing 5 to 15% by weight of Si and also containing Al and inevitable impurities as the remainder.

The bonding interface 20 between the ceramic plate 12 and the bonding layer 16 may include a Mg-containing layer 24. It is considered that the Mg-containing layer 24 present in the bonding interface 20 improves the bond strength between the ceramic plate 12 and the bonding layer 16, and that as a result, a high bond strength can be achieved between the ceramic plate 12 and the MMC plate 14. The Mg-containing layer 24 is identified as a layer containing Mg at a higher concentration than its periphery in the bonding interface 20, in an elemental mapping image acquired by an EPMA (electron probe micro analyzer). The Mg-containing layer 24 preferably further contains Al and O. In this case, the weight ratio Al:Mg:O in the Mg-containing layer 24 is preferably with in the range of 1:0.01 to 0.50:0.001 to 0.100, and more preferably 1:0.05 to 0.30:0.005 to 0.050. The weight ratio Al:Mg:O can be determined by an EPMA. The thickness of the Mg-containing layer 24 is preferably 1 to 10 μm and more preferably 1 to 7 μm, in view of improvement in the bond strength.

The bonding of the ceramic plate 12, the bonding layer 16, and the MMC plate 14 is preferably thermal compression bonding. Thermal compression bonding is a method including sandwiching a metal bonding film (corresponding to the bonding layer 16) between two members to be bonded to each other and bonding the two members by pressing them while heating at a temperature less than the liquidus temperature of the metal bonding film (see Patent Literature 1).

As illustrated in FIG. 2, the MMC plate 14 preferably includes an Al-rich layer 26 in which Al is distributed at a higher concentration than in other regions of the MMC plate 14 over a predetermined depth D_{Al} from the bonding interface 22 between the bonding layer 16 and the MMC plate 14. As stated hereinabove, a high bond strength between the MMC plate 14 and the ceramic plate 12 can be achieved by providing the Al-rich layer 26. It can be said that the Al-rich layer 26 is typically a layer in which Al derived from the bonding layer 16 is diffused to become rich. However, the MMC plate 14 itself may contain Al, and thus, the origin of Al in the Al-rich layer 26 is not of concern. The Al-rich layer 26 is identified as a layer containing Al at a higher concentration (than the other region in the MMC plate 14) and found in the region adjacent to the bonding interface 22 in the MMC plate 14, in an Al elemental mapping image acquired by an EPMA, as illustrated in FIG. 5B, which will be described later. Specifically, when pixels indicating high Al concentration in the Al elemental mapping image continuously distribute from the bonding layer 16 to the region adjacent to the bonding interface 22 in the MMC plate 14, it can be said that the Al at high concentration found in the adjacent region in the MMC plate 14 is Al derived from the bonding layer 16. Thus, the Al-rich layer 26 is identified. The depth D_{Al} of the Al-rich layer 26 is preferably 40 μm or more, more preferably 40 to 600 μm, even more preferably 50 to 500 μm, and particularly preferably 250 to 500 μm.

As illustrated in FIG. 2, the MMC plate 14 may include, in addition to the Al-rich layer 26, a Mg-diffused layer 28 in which Mg derived from the bonding layer 16 is diffused over a predetermined depth D_{Mg} from the bonding interface 22 between the bonding layer 16 and the MMC plate 14. In this case, the Al-rich layer 26 at least partially overlaps the Mg-diffused layer 28 (in other words, a portion that corresponds to both the Al-rich layer 26 and the Mg-diffused layer 28 is present in the MMC plate 14). It is considered that the Mg-diffused layer 28 also contributes to the achievement of a higher bond strength together with the Al-rich layer 26. The Mg-diffused layer 28 is identified as a layer containing Mg at a higher concentration (than the other region in the MMC plate 14) and found in the region adjacent to the bonding interface 22 in the MMC plate 14, in a Mg elemental mapping image acquired by an EPMA, as illustrated in FIG. 5B, which will be described later. Specifically, if pixels indicating high Mg concentration continuously distribute from the bonding layer 16 to the region adjacent to the bonding interface 22 in the MMC plate 14 in the Mg elemental mapping image, it can be said that the Mg at high concentration found in the adjacent region in the MMC plate 14 is Mg derived from the bonding layer 16. Thus, the Mg-diffused layer 28 is identified. The depth D_{Mg} of the Mg-diffused layer 28 is preferably 10 to 300 μm, more preferably 20 to 200 μm, and even more preferably 90 to 180 μm. Typically, the depth D_{Al} of the Al-rich layer 26 is greater than the depth D_{Mg} of the Mg-diffused layer 28 (i.e., D_{Al}>D_{Mg} is satisfied).

The MMC plate 14 may have an inner space that may be, for example, a flow channel through which a coolant is allowed to pass through. This allows the MMC plate 14 to have a configuration suitable as a cooling plate of an electrostatic chuck assembly.

The bonded body 10 preferably has a bond strength of 200 MPa or more, more preferably 250 MPa or more, and even more preferably 300 MPa or more, in four point bending test. The four point bending test is carried out in the procedure and conditions disclosed in Examples, which will be described later, and the maximum bending stress to be thus obtained is used as the bond strength. Since a higher bond strength is desirable, the upper limit thereof is not particularly limited, and the bond strength is typically 500 MPa or less, and more typically 450 MPa or less.

### Method for Producing Bonded Body

The bonded body of the present invention may be produced any method as long as the resultant bonded body has the specific layer structure. A preferable production method will be described below.

First, a ceramic plate having an embedded inner electrode, an MMC plate, and a bonding layer are provided. Details of each member are as described hereinabove. All of the ceramic plate, the MMC plate, and the bonding layer to be used may be known ones, or may be appropriately produced by known methods.

Next, the ceramic plate, the MMC plate, and the bonding layer are ultrasonically washed with an organic solvent. Soil adhered to the surface of each member can be removed by the ultrasonically washing, so that the adhesiveness of each member to the bonding layer can be improved to result in high bond strength. Preferable examples of the organic solvent include acetone and isopropyl alcohol (IPA). More soil can be removed by the ultrasonically washing for a longer duration, so that migration and diffusion of elements such as Mg and Al during the thermal compression bonding can be facilitated. Thus, control of the duration of the ultrasonically washing can regulate formation/non-formation of the Mg-containing layer and can change the depth (thickness) of the Al-rich layer and the depth (thickness) of the Mg-containing layer, in the following thermal compression bonding. For example, when the ultrasonically washing is carried out for a longer duration, the Mg-containing layer can be formed and also the depth of the Al-rich layer and the depth of the Mg-containing layer can increase. In view of effectively removing the soil adhered to the surface of each member, it is desirable to carry out both of ultrasonically washing with acetone and that with isopropyl alcohol (IPA). The ceramic plate and the MMC plate that have been ultrasonically washed are preferably further cleaned by washing with running pure water, blowing with N₂ gas, wiping with a wipe sheet impregnated with an organic solvent (such as IPA), and drying. The bonding layer that has been ultrasonically washed is preferably further cleaned by blowing with N₂ gas.

The ceramic plate, the MMC plate, and the bonding layer each thus cleaned are used for thermal compression bonding to prepare a bonded body. For example, the ceramic plate and the MMC plate may be bonded to each other via the bonding layer by sandwiching the bonding layer between the ceramic plate and the MMC plate, and thermal compression bonding the resultant at a pressure of 4 MPa to 30 MPa while heating at a temperature less than the liquidus temperature of the film of the bonding material. The temperature of the thermal compression bonding is desirably less than the liquidus temperature of the bonding layer, and more than a temperature less than the solidus temperature of the bonding layer by about 30° C. For example, an aluminum alloy containing 10 weight % of Si and 1 weight % of Mg has a liquidus temperature of about 590° C. and a solidus temperature of about 560° C. Accordingly, it can be said that in this case, the temperature of the thermal compression bonding is desirably about 520° C. or more and less than about 540° C. In this manner, the bonded body of the present invention including a ceramic plate and an MMC plate bonded to each other via a bonding layer can be obtained.

### EXAMPLES

The present invention will further be described specifically by way of Examples below. However, the present invention is not limited to Examples below.

### Examples 1 to 9

### (1) Preparation of Ceramic Plate

A disk-shaped sintered body (thickness: 5 mm, diameter 300 mm) of aluminum oxide having an embedded ESC electrode was prepared as a ceramic plate in the following manner. First, provided were the first and second disk-shaped green sheets made of alumina. An ESC electrode was formed on one side of the first green sheet by screen printing, and on the other hand, a heater electrode was formed on one side of the second green sheet by screen printing. Next, another green sheet made of alumina (hereinafter also referred to as the third green sheet) was laid on the side of the first green sheet on which the ESC electrode was formed, and the second green sheet was laid thereon such that the heater electrode was in contact with the third green sheet. The resulting layered body was fired by hot pressing, to thereby obtain a ceramic sintered body having the embedded ESC electrode and heater electrode. Working, such as grinding and blasting, was carried out on the both sides of the resulting ceramic sintered body to adjust the shape and the thickness, to obtain a ceramic plate as a plate-shaped electrostatic chuck. The specific conditions for producing the electrostatic chuck were set with reference to the conditions described in JP2006-196864A.

### (2) Preparation of MMC Plate

A plate containing Si, C, and Ti (SiSiCTi plate) as an MMC plate was prepared in the following manner. First, provided as starting materials were an SiC material (commercially available product having a purity of 97% or more and an average particle size of 15.5 μm), a metallic Si material (commercially available product having a purity of 97% or more and an average particle size of 9.0 μm), and a metallic Ti material (commercially available product having a purity of 99.5% or more and an average particle size of 31.1 μm). The SiC material, the metallic Si material, and the metallic Ti material were weighted such that the blending percentages were SiC: 49.5 mass %, Si: 20.0 mass %, and Ti: 30.5 mass %, and these materials together with isopropyl alcohol as a solvent were placed in a nylon-made pot and wet-mixed for 4 hours with iron core-containing nylon balls having a diameter of 10 mm. The resulting slurry was taken out, dried in nitrogen flow at 110° C., and allowed to pass through a 30-mesh sieve to obtain a formulated powder. The formulated powder was subjected to uniaxial press-molding at a pressure of 200 kgf/cm² to prepare a disk-shaped body having a diameter of about 50 mm and a thickness of about 17 mm, which was placed in a graphite mold for firing. The disk-shaped body was fired while hot pressing, to thereby obtain an MMC plate. The firing while hot pressing was carried out by keeping at a firing temperature (highest temperature) of 1400° C. for 4 hours in evacuated environment while pressing at a pressure of 200 kgf/cm².

For the MMC plate thus prepared, the arithmetic mean roughness Ra was measured on its surface to which the bonding layer was to be bonded, using a stylus-type surface roughness meter in accordance with JIS B 0601-2001. The result was as shown in Table 1.

### (3) Provision of Bonding Layer

An Al alloy sheet containing Si and Mg and having a thickness of 0.12 mm (alloy composition: Si: 10% by weight, Mg: 1% by weight, balance: Al and inevitable impurities) was provided to use as a bonding layer.

### (4) Cleaning

The following cleaning steps (i) to (v) were carried out in this order on each of the ceramic plate and the MMC plate, and on the other hand, only the following cleaning steps (i), (ii), and (vi) were carried out in this order on the Al alloy sheet containing Si and Mg.

### <Cleaning Steps>

(i) ultrasonically washing with acetone (not carried out in Example 9)
(ii) ultrasonically washing with isopropyl alcohol (IPA) (not carried out in Example 9)
(iii) washing with running pure water
(iv) blowing with N₂ gas
(v) drying at 120° C. for 10 minutes

In these steps, the total washing time of (i) ultrasonically washing with acetone and (ii) ultrasonically washing with isopropyl alcohol (IPA), that is, the duration of ultrasonically washing with organic solvents was varied in Experimental Examples as shown in Table 1. Thus, the ultrasonically washing (i) and (ii) were not carried out in Example 9 as described above.

### (5) Thermal Compression Bonding

The ceramic plate, the MMC plate, and the bonding sheet each cleaned were subjected to thermal compression bonding in the following manner. Specifically, the bonding sheet as a bonding layer was sandwiched between the ceramic plate and the MMC plate, and these were subjected to thermal compression bonding by heating in vacuo at 530° C. (temperature less than the liquidus temperature of the Al alloy containing Si and Mg, and more than a temperature less than the solidus temperature of the alloy by about 30° C.) at a pressure of 20 MPa, to thereby bond the ceramic plate, the bonding sheet (bonding layer), and the MMC plate to each other. Thus, a bonded body was obtained that had a ceramic plate and an MMC plate bonded to each other via a bonding layer.

### (6) Evaluation of Bonded Body

The following evaluation was made on the bonded body prepared.

### <Acquisition of Elemental Mapping Image by EPMA>

The bonded body obtained was cut to obtain its cross section, and the cross section was mirror-polished. Flat ion milling with Ar ions was carried out on the cross section, to obtain a cross section for observation. Observation was made using a SEM (scanning electron microscope) on an area of 75 μm×75 μm including the ceramic plate 12, the bonding interface 20, and the bonding layer 16 in the resulting cross section for observation. On that area, elemental analysis was carried out using an EPMA (manufactured by JEOL Ltd.) in a measurement condition of an acceleration voltage of 15 kV, to acquire an elemental mapping image for Si, C, Ti, O, Mg, and Al. FIGS. 3A and 3B show a SEM image (Compo image) of the cross section including the ceramic plate 12, the bonding interface 20, and the bonding layer 16 of the bonded body according to Example 7, and the various elemental mapping images of the area corresponding to the SEM image. As a result, as shown in Table 1 and FIGS. 3A and 3B, a Mg-containing layer 24 having a higher Mg concentration than that of its periphery was found at the bonding interface 20 in the bonded bodies according to Examples 1 to 7 and it was also found that the Mg-containing layer 24 further contains Al and O. On the other hand, such a Mg-containing layer was not found in the bonded bodies according to Examples 8 and 9 (Comparative Examples).

Observation using a SEM and elemental analysis using an EPMA were also made in the same manner as above on an area of 75 μm×75 μm including the bonding layer 16, the bonding interface 22, and the bonding interface 22 in the resulting cross section for observation. FIGS. 4A and 4B show a SEM image (Compo image) of the cross section including the bonding layer 16, the bonding interface 22, and the MMC plate 14 of the bonded body according to Example 7, and the various elemental mapping images of the area corresponding to the SEM image. As a result, microstructures including TiC particles (see black particles in the figure), a TiSi₂ parent phase (see gray portions in the figure), and SiC particles (see white particles in the figure) in the MMC plate 14 (SiSiCTi plate) as shown in FIGS. 4A and 4B were found in all bonded body according to Examples 1 to 9. It was also found that, in bonded bodies according to Examples 1 to 7, Mg and Al were diffused in SiSiCTi forming the MMC plate 14.

Furthermore, observation using a SEM and element analysis using an EPMA was also made on a larger area of 300 μm×300 μm including the bonding layer 16, the bonding interface 22, and the bonding interface 22 in the cross section in the same manner as above, except that the magnification was decreased and the concentration scale was reduced. FIGS. 5A and 5B show a SEM image (Compo image) of the cross section including the bonding layer 16, the bonding interface 22, and the MMC plate 14 of the bonded body according to Example 7, and the various elemental mapping images of the area corresponding to the SEM image, the elemental mapping images being versions on a reduced concentration scale. As a result, in bonded bodies according to Examples 1 to 9, it was found that an Al-rich layer 26 and a Mg-diffused layer 28 were present in the MMC plate 14, and it was inferred that, in the Al-rich layer 26 and the Mg-diffused layer 28, Al and Mg, respectively, derived from the bonding layer 16 were diffused from the bonding interface 22 in the depth direction of the MMC plate 14. The depth D_{Al} of the Al-rich layer 26 from the bonding interface 22 and the depth D_{Mg} of the Mg-diffused layer 28 from the bonding interface 22 were measured, and as a result, were found to be the values as shown in Table 1.

### <Weight Ratio Al:Mg:O in Mg-Containing Layer>

From the determination results by the EPMA, a semi-quantitative amount of each element was calculated in every pixel, which corresponded to 0.24 μm×0.24 μm, and the weight ratio was calculated from the average from 300 pixels to obtain the weight ratio Al:Mg:O. As a result, the weight ratio Al:Mg:O in the Mg-containing layer was 1:0.134:0.0238 (Example 1), 1:0.413:0.0961 (Example 2), 1:0.253:0.0479 (Example 3), 1:0.250:0.0532 (Example 4), 1:0.233:0.0196 (Example 5), 1:0.018:0.0099 (Example 6), 1:0.141:0.0321 (Example 7).

### <Bond Strength>

From the bonded body obtained, a long sample was cut out such that the bonding layer was positioned at the longitudinal center, and the surface of the sample was polished to prepare a specimen having dimensions of 1.5 mm×2.0 mm×20 mm. On this specimen, four point bending test was carried out such that the bonding interface was positioned at the center under the conditions of a lower span of 15 mm, an upper span of 5 mm, and a cross head speed of 0.5 mm/min, and the found maximum bending stress (MPa) was used as the bond strength. The results were as shown in Table 1.

TABLE 1

| | | | | Duration of | Ra of surface of | Depth D_{Al} | Depth D_{Mg} of | |
|---|---|---|---|---|---|---|---|---|
| | Composition | | | ultrasonically | MMC plate on | of Al-rich | Mg-diffused | Bond |
| | Ceramic | Bonding | | washing with organic | bonding interface | layer in MMC | layer in MMC | strength |
| | plate | layer | MMC plate | solvents (min) | side (μm) | plate (μm) | plate (μm) | (MPa) |
| Ex. 1 | Al₂O₃ | Al—Si—Mg | SiSiCTi | 2.5 | 0.921 | 50 | 20 | 260 |
| Ex. 2 | Al₂O₃ | Al—Si—Mg | SiSiCTi | 3 | 0.022 | 230 | 60 | 270 |
| Ex. 3 | Al₂O₃ | Al—Si—Mg | SiSiCTi | 5 | 0.809 | 500 | 100 | 300 |
| Ex. 4 | Al₂O₃ | Al—Si—Mg | SiSiCTi | 3 | 0.050 | 460 | 120 | 320 |
| Ex. 5 | Al₂O₃ | Al—Si—Mg | SiSiCTi | 8 | 0.503 | 480 | 180 | 320 |
| Ex. 6 | Al₂O₃ | Al—Si—Mg | SiSiCTi | 2 | 0.182 | 90 | 40 | 270 |
| Ex. 7 | Al₂O₃ | Al—Si—Mg | SiSiCTi | 5 | 0.156 | 250 | 90 | 335 |
| Ex. 8* | Al₂O₃ | Al—Si—Mg | SiSiCTi | 1 | 0.016 | 30 | 5 | 180 |
| Ex. 9* | Al₂O₃ | Al—Si—Mg | SiSiCTi | 0 | 0.221 | 20 | 5 | 160 |

*represents Comparative Example

### Examples 10 to 12

A bonded body was prepared and evaluated as in Example 1, except for i) using as an MMC plate a plate containing Si, C, Ti, and Al (SiSiCTi+Al plate) prepared in the following manner, and ii) changing the duration of ultrasonically washing with an organic solvent as shown in Table 2. The results were as shown in Table 2.

### (Preparation of MMC Plate)

A plate containing Si, C, Ti, and Al (provided that Al might be in the form of AlN) as an MMC plate was prepared in the following manner. First, provided as starting materials were an SiC material (commercially available product having a purity of 97% or more and an average particle size of 15.5 μm), a metallic Si material (commercially available product having a purity of 97% or more and an average particle size of 9.0 μm), a metallic Ti material (commercially available product having a purity of 99.5% or more and an average particle size of 31.1 μm), and an AlN material (commercially available product having a purity of 97% or more and an average particle size of 1.1 μm). The SiC material, the metallic Si material, the metallic Ti material, and the AlN material were weighted such that the blending percentages were SiC: 49.5% by mass, Si: 10.0% by mass, Ti: 30.5% by mass, and AlN: 10.0% by mass, and these materials together with isopropyl alcohol as a solvent were placed in a nylon-made pot and wet-mixed for 4 hours with iron core-containing nylon balls having a diameter of 10 mm. The resulting slurry was taken out, dried in nitrogen flow at 110° C., and then allowed to pass through a 30-mesh sieve to obtain a formulated powder. The formulated powder was subjected to uniaxial press-molding at a pressure of 200 kgf/cm² to prepare a disk-shaped body having a diameter of about 50 mm and a thickness of about 17 mm, which was placed in a graphite mold for firing. The disk-shaped body was fired while hot pressing, to thereby obtain an MMC plate. The firing while hot pressing was carried out by keeping at a firing temperature (highest temperature) of 1400° C. for 4 hours in evacuated environment while pressing at a pressure of 200 kgf/cm².

### Examples 13 to 18

A bonded body was prepared and evaluated as in Example 1, except for i) using an Al—Si bonding layer free from Mg prepared in the following manner, ii) carrying out the thermal compression bonding in the following manner, and iii) changing the duration of ultrasonically washing with an organic solvent as shown in Table 2. The results were as shown in Table 2.

### (Provision of Bonding Layer)

An Si and Al alloy sheet having a thickness of 0.12 mm (alloy composition: Si: 10% by weight, balance: Al and inevitable impurities) was provided to use as a bonding layer.

### (Thermal Compression Bonding)

The ceramic plate, the MMC plate, and the bonding sheet each cleaned were subjected to thermal compression bonding in the following manner. Specifically, the bonding sheet as a bonding layer was sandwiched between the ceramic plate and the MMC plate, and these were subjected to thermal compression bonding by heating in vacuo at 560° C. (temperature less than the liquidus temperature of the Si and Al alloy, and equal to or more than a temperature less than the solidus temperature of the alloy by about 30° C.) at a pressure of 20 MPa, to thereby bond the ceramic plate, the bonding sheet (bonding layer), and the MMC plate to each other. Thus, a bonded body was obtained that had a ceramic plate and an MMC plate bonded to each other via a bonding layer.

### Examples 19 to 21

A bonded body was prepared and evaluated as in Example 13, except for i) using as an MMC plate a plate containing Si, C, Ti, and Al (AlN) (SiSiCTi+Al(AlN) plate) prepared in the same manner as in Example 10, and ii) changing the duration of ultrasonically washing with an organic solvent as shown in Table 2. The results were as shown in Table 2.

### Examples 22 to 24

A bonded body was prepared and evaluated as in Example 13, except for i) using as an MMC plate a plate containing Si, C, and Al (AlSiCTi plate) prepared in the following manner, and ii) changing the duration of ultrasonically washing with an organic solvent as shown in Table 2. The results were as shown in Table 2.

### (Preparation of MMC Plate)

A plate containing Si, C, and Al as an MMC plate was prepared in the following manner. First, 5 parts by mass of PVB (polyvinyl butyral) as a binder and 5 parts by mass of colloidal silica were added to 100 parts by mass of a SiC material as a starting material powder, and the resulting mixture was pressure-molded to thereby prepare a porous ceramic molded body (preform). The resulting preform was preheated at 700° C., and the preheated preform was placed inside a mold of a pressurizing apparatus. Next, an aluminum alloy (AC3A) in a molten state at 750° C. was poured into the mold, followed by applying a pressure of 30 MPa to infiltrate the molten aluminum alloy into the preform. The infiltration treatment was carried out for 10 minutes. Then, the SiC with the aluminum alloy infiltrated thereinto, a composite material, was taken out from the mold, and excess aluminum alloy adhering to the periphery of the composite material was removed by grinding, to thereby obtain an MMC plate made of an Al—SiC composite material having a SiC content of 70% by volume.

### Examples 25 to 27

A bonded body was prepared and evaluated as in Example 19, except for i) using as a ceramic plate an aluminum nitride sintered body prepared in the following manner, and ii) changing the duration of ultrasonically washing with an organic solvent as shown in Table 2. The results were as shown in Table 2.

### (Preparation of Ceramic Plate)

A disk-shaped aluminum nitride sintered body (thickness: 5 mm, diameter 300 mm) having an embedded ESC electrode was prepared as a ceramic plate in the following manner. First, provided were the first and second disk-shaped green sheets made of aluminum nitride. An ESC electrode was formed on one side of the first green sheet by screen printing, and on the other hand, a heater electrode was formed on one side of the second green sheet by screen printing. Next, another green sheet made of aluminum nitride (hereinafter referred to as the third green sheet) was laid on the side of the first green sheet on which the ESC electrode was formed, and the second green sheet was laid thereon such that the heater electrode was in contact with the third green sheet. The resulting layered body was fired by hot pressing, to thereby obtain a ceramic sintered body having the embedded ESC electrode and heater electrode. Working, such as grinding and blasting, was carried out on both sides of the resulting ceramic sintered body to adjust the shape and the thickness, to obtain a plate-shaped electrostatic chuck as a ceramic plate.

TABLE 2

| | | | | Duration of | Ra of surface of | Depth D_{Al} | Depth D_{Mg} of | |
|---|---|---|---|---|---|---|---|---|
| | Composition | | | ultrasonically | MMC plate on | of Al-rich | Mg-diffused | Bond |
| | Ceramic | Bonding | | washing with organic | bonding interface | layer in MMC | layer in MMC | strength |
| | plate | layer | MMC plate | solvents (min) | side (μm) | plate (μm) | plate (μm) | (MPa) |
| Ex. 10 | Al₂O₃ | Al—Si—Mg | SiSiCTi + Al(AlN) | 5 | 0.312 | 480 | 120 | 320 |
| Ex. 11 | Al₂O₃ | Al—Si—Mg | SiSiCTi + Al(AlN) | 2.5 | 0.571 | 70 | 30 | 300 |
| Ex. 12* | Al₂O₃ | Al—Si—Mg | SiSiCTi + Al(AlN) | 1 | 0.209 | 20 | 5 | 180 |
| Ex. 13 | Al₂O₃ | Al—Si | SiSiCTi | 5 | 0.682 | 490 | — | 310 |
| Ex. 14 | Al₂O₃ | Al—Si | SiSiCTi | 3 | 0.591 | 400 | — | 320 |
| Ex. 15 | Al₂O₃ | Al—Si | SiSiCTi | 2.5 | 0.233 | 120 | — | 270 |
| Ex. 16 | Al₂O₃ | Al—Si | SiSiCTi | 2 | 0.108 | 80 | — | 270 |
| Ex. 17* | Al₂O₃ | Al—Si | SiSiCTi | 1 | 0.314 | 30 | — | 160 |
| Ex. 18* | Al₂O₃ | Al—Si | SiSiCTi | 0 | 0.601 | 20 | — | 180 |
| Ex. 19 | Al₂O₃ | Al—Si | SiSiCTi + Al(AlN) | 5 | 0.224 | 460 | — | 330 |
| Ex. 20 | Al₂O₃ | Al—Si | SiSiCTi + Al(AlN) | 2.5 | 0.129 | 60 | — | 310 |
| Ex. 21* | Al₂O₃ | Al—Si | SiSiCTi + Al(AlN) | 1 | 0.576 | 20 | — | 160 |
| Ex. 22 | Al₂O₃ | Al—Si | AiSiC | 5 | 0.958 | 60 | — | 270 |
| Ex. 23 | Al₂O₃ | Al—Si | AiSiC | 2.5 | 0.697 | 80 | — | 280 |
| Ex. 24* | Al₂O₃ | Al—Si | AiSiC | 1 | 0.941 | 30 | — | 150 |
| Ex. 25 | AlN | Al—Si | SiSiCTi + Al(AlN) | 5 | 0.741 | 490 | — | 320 |
| Ex. 26 | AlN | Al—Si | SiSiCTi + Al(AlN) | 2.5 | 0.298 | 100 | — | 290 |
| Ex. 27* | AlN | Al—Si | SiSiCTi + Al(AlN) | 1 | 0.131 | 30 | — | 180 |

*represents Comparative Example

### REFERENCE SIGNS LIST

10 Bonded body
12 Ceramic plate
14 MMC plate
16 Bonding layer
18 Inner electrode
20, 22 Bonding interface
24 Mg-containing layer
26 Al-rich layer
28 Mg-diffused layer

What is claimed is:

1. A bonded body comprising:
a ceramic plate;
a metal matrix composite (MMC) plate facing one side of the ceramic plate and made of an MMC comprising (i) Si, C, and Ti, or (ii) Al, Si, and C; and
a bonding layer interposed between the ceramic plate and the MMC plate and bonding the ceramic plate and the MMC plate to each other, wherein the bonding layer comprises Al as a main component,
wherein the MMC plate includes an Al-rich layer in which Al is distributed at a higher concentration than in other regions of the MMC plate over a predetermined depth D_{Al} from a bonding interface between the bonding layer and the MMC plate, and the depth D_{Al} of the Al-rich layer is 40 μm or more.

2. The bonded body according to claim 1, wherein the metal matrix composite (MMC) comprises Si, C, and Ti, and further comprises Al, or Al and N.

3. The bonded body according to claim 1, wherein the metal matrix composite (MMC) comprises Al, Si, and C.

4. The bonded body according to claim 1, wherein the bonding layer further comprises Si as a subcomponent.

5. The bonded body according to claim 4, wherein the bonding layer further comprises Mg as a subcomponent.

6. The bonded body according to claim 5, wherein the MMC plate includes a Mg-diffused layer in which Mg derived from the bonding layer is diffused over a predetermined depth D_{Mg} from a bonding interface between the bonding layer and the MMC plate.

7. The bonded body according to claim 6, wherein the depth D_{Al} of the Al-rich layer is greater than the depth D_{Mg} of the Mg-diffused layer to satisfy D_{Al}>D_{Mg}.

8. The bonded body according to claim 1, wherein the ceramic plate comprises aluminum oxide and/or aluminum nitride, and comprises an embedded inner electrode.

9. The bonded body according to claim 1, wherein the bonding of the ceramic plate, the bonding layer, and the MMC plate is thermal compression bonding.

10. The bonded body according to claim 1, wherein a surface of the MMC plate, on the bonding interface side, has an arithmetic mean roughness Ra of 0.01 to 1.0 μm.

11. The bonded body according to claim 1, having a bond strength of 200 MPa or more in four point bending test.
